(19) United States
(12) Patent Application Publication
(10) Pub. No.: US 2023/0182829 A1
(43) Pub. Date: Jun. 15, 2023

(54) Roof Module for Forming a Vehicle Roof with a Cooling Feature

(71) Applicant: Webasto SE, Stockdorf (DE)

(72) Inventors: Michael HUELSEN, Stockdorf (DE); Juraj LEHOTSKY, Stockdorf (DE); Markus GEY, Stockdorf (DE); Maximilian EHRMANN, Stockdorf (DE)

(21) Appl. No.: 17/882,890

(22) Filed: Aug. 8, 2022

(30) Foreign Application Priority Data
Aug. 10, 2021 (DE) 10 2021 120 776.2

(51) Int. Cl. B62D 25/24; B62D 25/06; G01S 7/02; G01S 13/931; G01K 3/00

(52) U.S. Cl. CPC B62D 25/24; B62D 25/06; G01S 7/027; G01S 13/931; G01K 3/005; G01S 2013/9323; G01S 2013/93273

(57) ABSTRACT

A roof module for forming a vehicle roof on a motor vehicle may have a panel component whose outer surface at least partially forms a roof skin of the vehicle roof; at least one environment sensor configured to send and/or receive electromagnetic signals for detecting the vehicle environment and disposed at least partially below the roof skin formed by the panel component; and a cooling feature configured to discharge waste heat emitted by the environment sensor and/or externally introduced heat from the environment sensor. The cooling feature may have at least one cooling channel in which at least two cooling fans are disposed, the cooling fans being connected to at least one controller of the cooling feature.

### CROSS-REFERENCE TO RELATED APPLICATION

This application claims priority from German patent application no. 10 2021120 776.2, filed on Aug. 10, 2021, which is hereby incorporated herein by reference in its entirety for all purposes.

### FIELD

The invention relates to a roof module for forming a vehicle roof on a motor vehicle according to the preamble of claim 1.

### BACKGROUND

Generic roof modules are widely used in vehicle manufacturing since these roof modules can be prefabricated as separate functional modules and can be delivered to the assembly line when assembling the vehicle. The roof module at least partially forms a roof skin of the vehicle roof at its outer surface, the roof skin preventing moisture or air flows from entering the vehicle interior. The roof skin is formed by one or more panel components, which can be made of a stable material, such as painted metal or painted or dyed-through plastic. The roof module can be a part of a rigid vehicle roof or a part of an openable roof subassembly.

Furthermore, the development in vehicle manufacturing is increasingly focusing on autonomously or semi-autonomously driving motor vehicles. In order to enable the vehicle controller to control the motor vehicle autonomously or semi-autonomously, a plurality of environment sensors (e.g., lidar sensors, radar sensors, (multi-)cameras, etc. including other (electrical) components) are employed, which are integrated in the roof module, for example, and which detect the environment surrounding the motor vehicle and determine, for example, a current traffic situation from the detected environment data. Roof modules which are equipped with a plurality of environment sensors are also known as roof sensor modules (RSM). For this purpose, the known environment sensors send and/or receive suitable electromagnetic signals, such as laser beams or radar beams, allowing a data model of the vehicle environment to be generated by suitable signal evaluation and to be used for controlling the vehicle. In order to protect the environment sensors from harmful environmental conditions, such as moisture and air flows, the environment sensors are installed in a sensor housing or integrated in the roof module, for example. Irrespective of how they are installed, the environment sensors always protrude over an upper side of the roof skin formed by the roof module so that each environment sensor has a 360° view within its working area.

Optimal and reliable operation, safety, and availability of the autonomous or semi-autonomous driving mode requires the environment sensors and the other (electrical) components to be available at all times or without as little interruption as possible. An existing issue which can result in the (temporary) outage of an environment sensor is the occurrence of heat build-up around the environment sensor, which can cause the latter to overheat and therefore fail. Such a heat build-up may be caused not only by waste heat generated by the environment sensor during operation but alternatively or additionally also by a hot outdoor climate, e.g., at the height of summer, and lead to overheating (also just of individual electronic components of the environment sensor, for example). A hot outdoor climate or strong solar irradiation can cause the entire roof skin to heat up severely, in particular because of the exposed position of the environment sensors on top of the roof skin. Since the roof skin is often made of materials having a high thermal conduction capacity (e.g., metal), a high thermal flow from the outer side of the vehicle roof in the direction of the vehicle interior can occur, which may cause heat to build up in the installation spaces intended for the environment sensors, for example.

### SUMMARY

Hence, it is desirable for a potential heat build-up to be prevented by employing an effective cooling feature to avoid these heat-related issues. While the advantages of a use of such cooling features are conceptually known, they are not yet comprehensively applied in modern roof modules for the autonomous or semi-autonomous driving mode, which is why a continuous availability of the environment sensors cannot be guaranteed by effective heat discharge from the environment sensors, the antennas, and other electrical components at this time in some instances at least.

Another issue with the existing concepts for discharging heat from the environment sensors, the antennas, and other electrical components is that the cooling feature exhibits high noise emission, which can in particular negatively affect the driving comfort for a driver of the vehicle and thus make such a vehicle less attractive to buy. In particular, the ventilator used in cooling features operating with a forced air flow to provide heat discharge causes high noise emission (in particular in the case of a high volumetric flow rate and high speed).

The object of the invention is to propose a roof module which diminishes the disadvantages of the known state of the art described above.

This object is attained by a roof module according to the teaching of claim 1.

Advantageous embodiments of the invention are the subject matter of the dependent claims.

The roof module according to the invention for forming a vehicle roof on a motor vehicle comprises a panel component whose outer surface at least partially forms a roof skin of the vehicle roof. The roof module comprises at least one environment sensor configured to send and/or receive electromagnetic signals for detecting the vehicle environment and disposed at least partially below the roof skin formed by the panel component. The roof module comprises a cooling feature configured to discharge waste heat emitted by the environment sensor and/or externally introduced heat from the environment sensor. The roof module according to the invention is characterized in that the cooling feature comprises at least one cooling channel in which at least two cooling fans are disposed, the cooling fans being connected to at least one controller of the cooling feature. The cooling feature provided in or on the roof module thus makes it possible for a heat build-up within the roof module due to the waste heat emitted by the environment sensor and/or heat externally introduced by solar irradiation, for example, to be avoided. Waste heat emitted by the environment sensor or other heat can be discharged by means of the cooling feature, thereby avoiding an inadmissibly high operating temperature of the environment sensor. Thus, an undisturbed operation of the environment sensors can be ensured. The use of the controller according to the invention, which is connected to the at least two cooling fans, enables a thermal management which can ensure an effective, situation-optimized cooling of the environment sensors (and preferably additional antennas and electrical components provided in the roof module). According to the invention, the two cooling fans are disposed in the cooling channel, which extends on an underside of the roof skin, for example. The cooling feature preferably comprises multiple ventilation channels which are connected to one another in such a manner that an air flow can flow through the multiple cooling channels. The air flow, which absorbs the accumulating waste heat, is generated by the at least two fans, which ensures an efficient heat discharge. Moreover, the cooling feature according to the invention enables a very compact design, dimensioning, and arrangement of the cooling components in terms of installation space and additionally a cost-efficient selection of components.

Supply air for the cooling feature can be transported into the cooling feature (e.g., aspirated by the cooling fans) from outside of the vehicle, for example. The supply air is heated within the cooling feature (e.g., in the at least one cooling channel) and transported back outside by means of the air flow. Alternatively or additionally, the supply air can be transported into the cooling feature at least partially by diverting a preferably pre-cooled air flow from the air-conditioning circuit existing in the vehicle. The supply air is heated in the cooling feature by the waste heat to be discharged and is transported back into the air-conditioning circuit or outside by the air flow. The latter alternative has the advantage that a preferably pre-cooled supply air can absorb more heat because of the low temperature at which it enters the cooling feature, which increases the cooling effect.

The roof module according to the invention can form a structural unit in which features for autonomous or semi-autonomous driving assisted by driver assistance systems are integrated and which can be placed on top of a vehicle body shell as a unit by a vehicle manufacturer. Furthermore, the roof module according to the invention can be a purely fixed roof or a roof including a roof opening system. Moreover, the roof module can be configured for use in a passenger car or in a utility vehicle. The roof module can preferably be provided as a structural unit in the form of a roof sensor module (RSM) in which the environment sensors are provided so as to be inserted into a roof frame of a vehicle body as a suppliable structural unit.

The at least two cooling fans are disposed in series one behind the other or in parallel next to each other in the cooling channel to ensure a heat discharge and a temperature management as effective as possible. Disposing the cooling fans in series one behind the other is of particular advantage since this ensures an effective flow control or flow guidance in the cooling channel. If the controller runs both cooling fans simultaneously, for example, the cooling capacity, i.e., the volumetric flow rate produced by the at least two fans connected in series, is increased. In the case of such a series connection, the at least two cooling fans are connected one behind the other in the air flow, whereby an increase in pressure corresponding to the capacity of the respective cooling fans is achieved. Alternatively, the at least two cooling fans can also be disposed in parallel, i.e., next to each other, which increases the producible volumetric flow rate.

In case the cooling feature comprises at least one second cooling channel, the at least two cooling fans can also be disposed in different cooling channels.

Instead of two cooling fans, any number of additional cooling fans (e.g., three or four cooling fans) can of course be disposed in one or more cooling channels of the cooling feature in other embodiments of the invention. For example, any number of cooling fans can be connected in series and/or in parallel or be disposed in different cooling channels.

The at least two fans can of course also be connected to separate controllers. However, it is preferred for the cooling feature to only comprise one common controller. This controller can preferably also be the air-conditioning controller of the air-conditioning circuit of the vehicle so that control synergies can be utilized.

Moreover, it is noted that the at least one environment sensor is disposed at least partially below the roof skin formed by the panel component; thus, parts or portions of it protrude over the roof skin, i.e., the outer surface of the roof skin. So part of the environment sensor, e.g., part of a sensor housing, is disposed below the roof skin. The environment sensor can also be disposed entirely below the roof skin, meaning it does not protrude over the roof skin.

In a specific embodiment of the roof module, the roof skin comprises one or more solar cells which supply an electrical feature, e.g., the cooling fans, of the cooling feature with electrical energy to ensure an energy-saving operation of the cooling feature, in particular the at least two cooling fans, in particular in the parked state of the vehicle and to thus be able to keep the roof module at a predetermined use temperature even when the vehicle is stationary. Thus, the cooling fans including the at least one controller, for example, are operated using the electrical energy of the solar cells so that a heat discharge can be ensured even when the vehicle is stationary. This makes it possible to ensure a (pre-)cooling of the roof module, in particular of the environment sensors, before the vehicle is operated (the motor is started).

In an embodiment according to the invention, the at least two cooling fans particularly preferably have different maximum cooling capacities. For instance, a low-capacity cooling fan and a cooling fan of high capacity relative thereto can be employed. If a low cooling capacity is sufficient, the low-capacity cooling fan can thus be used. If a cooling capacity greater than that is needed, the high-capacity cooling fan can be used. If a very high cooling capacity is required, both cooling fans can be operated at maximum cooling capacity each, preferably while being connected in series. Alternatively, the at least two cooling fans can also have the same maximum capacity or even be identical.

It is preferred for the cooling fan having the greater cooling capacity to be disposed downstream of the cooling fan having the comparatively lower cooling capacity in the cooling channel. In the series connection in particular, this arrangement has the advantage that the lower-capacity cooling fan does not cause a deceleration of the cooling air leaving the higher-capacity cooling fan in the downstream direction.

In a preferred embodiment of the invention, the at least two cooling fans differ in terms of their respective dimensions, design, blade position, controllability, and/or maximum speed or maximum capacity. Thus, the cooling fans can generate different volumetric flow rates.

The term “dimensions” refers to the extension of each fan (e.g., a radius from an axis of rotation of the cooling fan to a blade tip of the rotor blades of the cooling fan) since this determines the volumetric flow rate that can be produced. The term “design” refers to, for example, the geometry of the rotor blades, a bearing of the rotor (which is as low-friction as possible), and other factors affecting the characteristic curve of the cooling fan and the working point. The term “blade position” refers to an angle of inclination (skew/rake) of each rotor blade and the number of rotor blades, these parameters also affecting the characteristic curve of the cooling fan and its working point. The term “controllability” means, for example, that the speed of one of the at least two cooling fans can be controlled, allowing said cooling fan to be operated at different speeds (at different working points). Another one of the at least two cooling fans, on the other hand, may only be operable at one working point (at a predetermined speed), thus receiving only an on or off instruction as a control instruction. Likewise, the cooling fans can differ in their (maximum) speed. For instance, one of the at least two cooling fans can be configured to rotate solely (i.e., quietly) and the other one of the at least two cooling fans can be configured to rotate fast. Of course, alternative embodiments may also employ two identical cooling fans.

According to the invention, it is preferred for the controller to be configured to control the at least two cooling fans in a multi-level manner. In this embodiment, the speed of the at least two cooling fans can preferably be controlled, and the at least two cooling fans can thus be operated at different working points along the respective characteristic curves of the cooling fans. For example, the controller can control one of the cooling fans to rotate at a lower speed, whereas it controls the other cooling fan to rotate at a higher speed compared thereto. This makes it possible for a plurality of different possible volumetric flow rates (capacities) to be generated by the cooling fans. This allows a multi-level operation, whereby different cooling fan capacities can be set for different (vehicle) operating modes or heat dissipation amounts. Thus, a high cooling capacity can be provided when the vehicle is started if the vehicle has been exposed to strong solar irradiation. During driving, on the other hand, when the built-up heat has been largely discharged, a low cooling capacity can be provided. In other words, it suffices to provide a low cooling capacity in the “normal, steady” vehicle operating mode when the system is in the operational temperature range, which means that the weaker, quieter cooling fan is operated at a low volumetric flow rate, for example. In this way, the noise emission can be advantageously adapted according to the situation by the multi-level control of the at least two cooling fans as a function of the operating mode of the vehicle.

In one embodiment, it is advantageous for the controller to be able to individually control each of the at least two cooling fans. Thus, each cooling fan can be controlled separately and different control instructions can be transmitted to each cooling fan in the form of electrical signals. However, the cooling fans are preferably not controlled independently but in a coordinated manner depending on the cooling situation. In a preferred embodiment, the controller is configured to control the respective speeds of the at least two cooling fans in a closed or open loop as a function of a required cooling capacity of the cooling feature. The required cooling capacity can be transmitted to the controller, for example, or it can be determined by the controller itself. The cooling capacity essentially depends on the waste heat produced by the environment sensors and/or the external irradiation heat and can change constantly during vehicle operation.

With regard to an effective temperature management in the roof module, it is advantageous for the roof module to comprise at least one temperature sensor by means of which the temperature in the roof module can be measured, particularly preferably in the area of the respective environment sensor. This makes it possible for the temperature of the environment sensor to be measured as directly at the temperature sensor as possible. By constantly comparing the measured temperature to a respective target temperature, the sensor can thus be monitored for an admissible temperature. If, for example, a temperature increase which exceeds a predetermined threshold is measured or registered (actual/target deviation), the controller can send a control instruction based on this information to the cooling fans that a higher cooling capacity is required to limit the determined temperature increase and to achieve cooling to below the target temperature as quickly as possible. It is particularly advantageous for the controller to receive the sensor data (information) of the temperature sensor and determine the required cooling capacity from them (preferably in real time).

The controller can thus particularly advantageously control the cooling capacity of the cooling feature in an open or closed loop as a function of the temperature measured by the temperature sensor by situationally controlling (the speed of) the cooling fans in an open or closed loop. In this way, the intended target temperature can be maintained or an intended threshold temperature is exceeded only briefly.

Additionally, it is also possible for the supply air to be humidified before entering the cooling feature so that it can absorb more heat. In this context, it is advantageous if it is constructively ensured (e.g., by means of seals) that an air flow humidified in this manner does not come into direct contact with the environment sensors so as to not damage them. To this end, the roof module preferably comprises a separate wet section. The cooling feature can be disposed in said wet section since an exchange of fluids through the wet section enables a particularly effective discharge of the waste heat, as described above. It is preferred for the environment sensors to be each disposed in a dry section of the roof module, which is protected against moisture, to protect the environment sensor from damage due to moisture. The waste heat emitted by the environment sensor will be discharged from the dry section into the wet section, heat build-up in the dry section thus being precluded.

The waste heat can be discharged from the dry section in the roof module in basically any manner. According to a preferred embodiment, the cooling feature comprises at least one thermally conductive element which is disposed in the cooling channel and by means of which the waste heat emitted by the environment sensor can be discharged, preferably from the dry section.

For a heat transfer of the heat to be discharged from the environment sensor to the thermally conductive element to be as unhindered as possible, it is particularly advantageous for the environment sensor to have a cooling surface. The environment sensor can come into contact with the thermally conductive element via said cooling surface to establish a heat transfer with low conduction resistance. It is particularly advantageous for a thermally conductive paste to be applied between the cooling surface and the thermally conductive element. Basically any type of thermally conductive element can be used for the heat conduction. The heat conduction is particularly effective if the thermally conductive element is formed by a heat pipe or a metal part. A heat pipe is a hollow body filled with cooling liquid and made of copper, for example. The efficient heat discharge through the heat pipe is typically achieved based on a continuous change of state of matter (vaporization in the hot part and condensation in the cold part), which causes fluid to circulate within the heat pipe. The coolant circuit can be open or closed. If a metal part is provided as the thermally conductive element, it can preferably a mounting plate. The mounting plate can be part of the vehicle body shell or the vehicle frame. The mounting plate can also be part of the roof module frame or a roof module support element which is part of the roof module. The heat can be discharged into other vehicle areas via the mounting plate.

According to a preferred embodiment, one or more cooling elements and/or heat exchangers by means of which waste heat or built-up heat (e.g., due to solar irradiation) at the sensors, antennas, and other electrical components can be transported away (e.g., directly into the environment or to another cooling element, heat exchanger, heat pump, etc.) via an air flow caused by the at least two cooling fans are disposed in the at least one cooling channel to increase the heat discharge capacity. It is particularly advantageous for the cooling element to have one or more cooling fins to increase the surface of the cooling element available for cooling. Cooling element fins of this kind are relatively compact and have a large cooling surface for transferring heat.

Basically any type of environment sensor can be installed in the roof module. The cooling provided in the roof module according to the invention is particularly advantageous if lidar sensors and/or radar sensors and/or camera sensors and/or multi-camera sensors are used.

### BRIEF DESCRIPTIONS OF THE DRAWINGS

An embodiment of the invention is schematically illustrated in the drawing and will be discussed in more detail as an example below.

FIG. 1A is a perspective view of a vehicle roof comprising a roof module according to the invention;

FIG. 1B is a partial view of a roof module according to the invention in a schematized cross section;

FIG. 2 shows a cooling channel having cooling fans connected in series;

FIG. 3 shows two exemplary embodiments of cooling fans;

FIG. 4 is a detail view of a cooling channel having cooling fans connected in series; and

FIG. 5 is a schematic view of a cooling feature including temperature sensors, heat pipes, and cooling elements.

### DETAILED DESCRIPTION

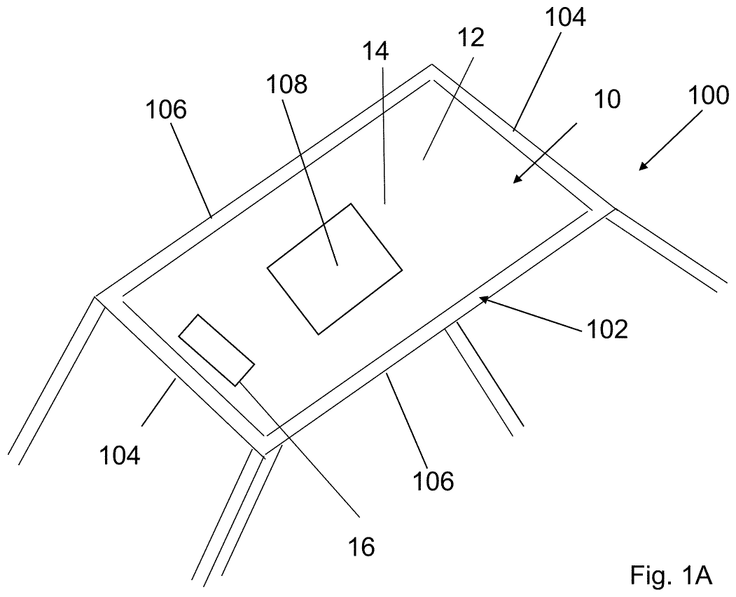

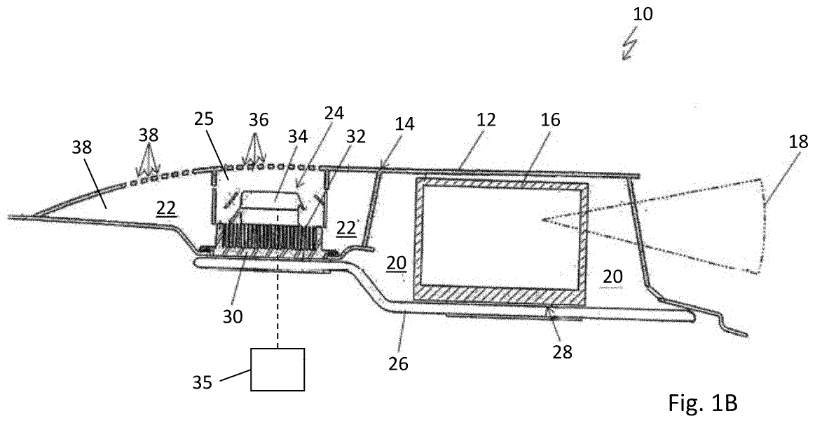

FIG. 1A shows a vehicle roof 100, which comprises a roof module 10. Roof module 10 comprises a panel component 12 for forming the roof skin 14 of the vehicle roof of a vehicle (not shown in full). An environment sensor 16 is disposed below roof skin 14, which is formed by panel component 12, environment sensor 16 being able to send and/or receive electromagnetic signals 18 on the side facing the vehicle front for detecting the vehicle environment (see FIG. 1B). Alternatively, the environment sensor can also be a (multi-)camera, for example, or any other known type of environment sensor. Roof module 10 is preferably inserted into a roof frame 102 of the vehicle or placed on top of transverse rails 104 and longitudinal rails 106, which form roof frame 102, as a structural unit. Roof skin 14 comprises one or more solar cells 108, which preferably supply a cooling feature 24 of roof module 10 with electrical energy (e.g., when the vehicle is stationary and the motor is turned off).

FIG. 1B shows a partial view of roof module 10 in a schematized cross section. In the partial view of FIG. 1B, only the parts of roof module 10 which are required for understanding the invention are illustrated. So roof module 10 is illustrated in simplified form.

Environment sensor 16 is disposed in a dry section 20, which is protected against moisture and which is encapsulated in a moisture-proof manner vis-à-vis the outside by means of seals, for example. Dry section 20 preferably comprises a thermally conductive outer casing (see FIG. 5). In this manner, environment sensor 16 is reliably protected against the entry of moisture.

A wet section 22 is provided behind or to the left of dry section 20 in roof module 10 with respect to FIG. 1B, wet section 22 being secluded from dry section 20 in a liquid-tight manner. Cooling feature 24 for discharging waste heat from roof module 10 and from environment sensor 16 is located in wet section 22. A thermally conductive element 26, which is formed by a heat pipe, extends between cooling feature 24 and environment sensor 16. A cooling surface 28 of environment sensor 16 is attached to the inner side of thermally conductive element 26, which faces dry section 20. In this manner, waste heat emitted by environment sensor 16 can be effectively transferred to thermally conductive element 26.

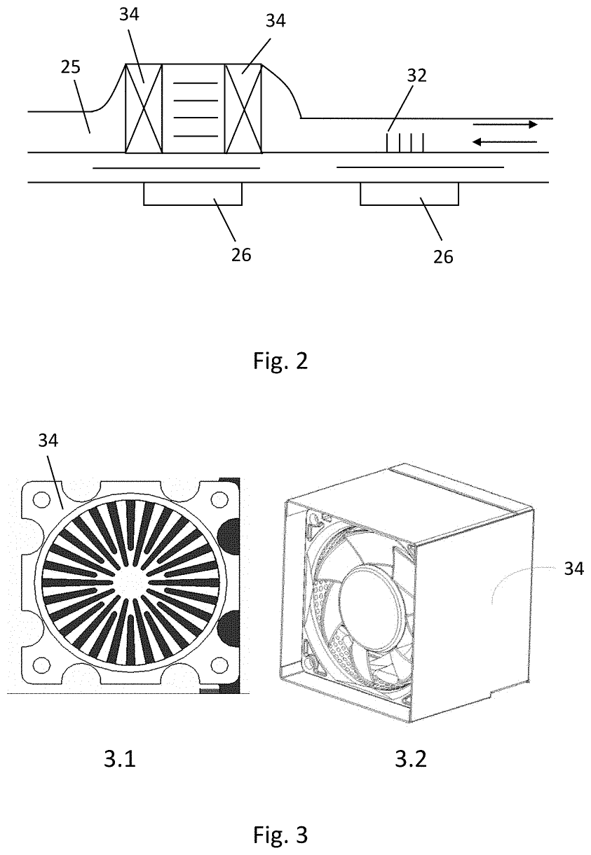

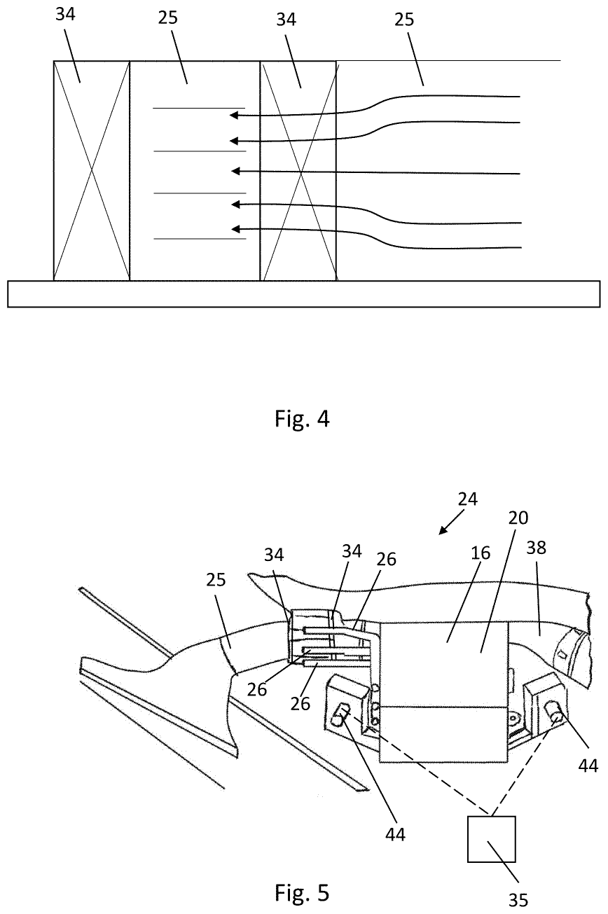

Heat flow in thermally conductive element 26 transfers the waste heat to cooling feature 24 in wet section 22. Cooling feature 24 comprises a first cooling channel 25. A cooling element (i.e., a thermally conductive element) 30 comprising a plurality of cooling fins 32 is disposed in first cooling channel 25. Cooling element 30 is fixed to the inner side of thermally conductive element 26, which faces wet section 22, in a thermally conductive manner with its bottom surface with the result that the waste heat led over in thermally conductive element 26 is transferred to cooling element 30 with low thermal resistance. This heats cooling fins 32 of cooling element 30. Cooling feature 24 further comprises two cooling fans 34, of which only one is visible in FIG. 1B. Cooling fans 34 are connected to a controller 35 either via one or more cables or wirelessly so that cooling fans 34 can receive one or more control signals from controller 35. Illustrative examples of cooling fan 34 are shown in FIG. 3. The two cooling fans 34 are connected in parallel or in series and disposed in first cooling channel 25 (see FIGS. 2 and 4). In the example illustrated in FIG. 1B, fresh air can be transported into wet section 22 through inlet openings 36. Cooling fans 34 generate an air flow, causing the fresh air to flow past cooling fins 32 and absorb the waste heat produced by environment sensor 16. The heated fresh air subsequently flows through a second cooling channel 38, which is connected to first cooling channel 25, and leaves wet section 22 through outlet openings 40. In this way, the waste heat can be fully discharged from roof module 10.

FIG. 5 schematically shows cooling feature 24. Here, cooling feature 24 has multiple cooling channels 25 and three heat pipes (i.e., thermally conductive elements) 26. Cooling fans 34 are only hinted at in FIG. 5 since they are disposed within a pipe section 42 of cooling channel 25 cooling channel 38. Pipe section 42 comprises cooling element 30 as a type of pipe casing or pipe collar of pipe section 42. Moreover, dry section 20 is encased with a cooling element (e.g., on an outer side of a housing of dry section 20) to ensure a heat conduction from dry section 20 to thermally conductive elements 26 as free from resistance as possible.

Two temperature sensors 44 are disposed in the immediate vicinity of environment sensor 16. Of course, only one temperature sensor 44 may be present in other embodiments. Thus, the temperature of environment sensor 16 can be measured. The capacity of cooling fan 34 can be proportionally increased by means of controller 35 depending on the temperature measured at temperature sensors 44 to effectively cool environment sensor 16. Controller 35 communicates with temperature sensors 44 via one or more cables or wirelessly and can consequently receive at least one or more signals of temperature sensors 44.

Fans 34 can differ in terms of their respective dimensions, design, blade position, controllability, and/or maximum speed, cooling fans 34 with different designs being schematically illustrated in FIGS. 3.1 and 3.2.

1. A roof module for forming a vehicle roof on a motor vehicle, the roof module comprising:
a panel component whose outer surface at least partially forms a roof skin of the vehicle roof;
at least one environment sensor configured to send and/or receive electromagnetic signals for detecting the vehicle environment and disposed at least partially below the roof skin formed by the panel component; and
a cooling feature configured to discharge waste heat emitted by the environment sensor and/or externally introduced heat from the environment sensor,
wherein the cooling feature comprises at least one cooling channel in which at least two cooling fans are disposed, the cooling fans being connected to at least one controller of the cooling feature.

2. The roof module according to claim 1, wherein the at least two cooling fans in the cooling channel are disposed in series one behind the other or in parallel next to each other.

3. The roof module according to claim 1, wherein the cooling feature comprises at least one second cooling channel, the at least two cooling fans being disposed in different cooling channels.

4. The roof module according to claim 1, wherein the at least two cooling fans each have a different maximum cooling capacity.

5. The roof module according to claim 4 wherein the cooling fan having the higher cooling capacity is disposed downstream of the cooling fan having the lower cooling capacity in the cooling channel.

6. The roof module according to claim 1, wherein the at least two cooling fans differ in terms of their respective dimensions, design, blade position, controllability, and/or maximum speed.

7. The roof module according to claim 1, wherein the controller is configured to control the at least two cooling fans in a multi-level manner.

8. The roof module according to claim 1, wherein the controller is configured to individually control each of the at least two cooling fans.

9. The roof module according to claim 1, wherein the controller is configured to control the respective speeds of the at least two cooling fans in a closed or open loop as a function of a required cooling capacity of the cooling feature.

10. The roof module according to claim 1, wherein the roof module comprises at least one temperature sensor configured to measure the temperature in the roof module in the area of the environment sensor.

11. The roof module according to claim 9, wherein the controller is configured to determine the required cooling capacity from the measured temperature.

12. The roof module according to claim 1, wherein the environment sensor is disposed in a dry section of the roof module, the dry section being protected against moisture, the cooling feature being configured to discharge waste heat emitted by the environment sensor from the dry section.

13. The roof module according to claim 1, wherein the cooling feature comprises at least one thermally conductive element disposed in the cooling channel, the thermally conductive element being configured to discharge waste heat emitted by the environment sensor.

14. The roof module according to claim 13, wherein the environment sensor has at least one cooling surface, the environment sensor being in contact with the thermally conductive element via the cooling surface.

15. The roof module according to claim 13, wherein the thermally conductive element is formed by a heat pipe or a metal part.

16. The roof module according to claim 1, wherein the cooling feature comprises a cooling element and/or a heat exchanger and/or a heat pump.

17. The roof module according to claim 16, wherein cooling element has at least one cooling fin.

18. The roof module according to claim 1, wherein the environment sensor is formed by a lidar sensor and/or a radar sensor and/or a camera sensor and/or a multi-camera sensor.

19. The roof module according to claim 1, wherein the roof skin comprises one or more solar cells configured to supply the at least two cooling fans and/or the at least one controller with electrical energy provided by the one or more solar cells.

20. A motor vehicle comprising a roof module according to claim 1.
